(19) United States
(12) Patent Application Publication
(10) Pub. No.: US 2011/0199813 A1
(43) Pub. Date: Aug. 18, 2011

(54) NON-VOLATILE MEMORY DEVICE HAVING 3D STRUCTURE AND METHOD FOR FABRICATING THE SAME

(76) Inventors: Hyun-Seung Yoo, Gyeonggi-do (KR); Eun-Seok Choi, Gyeonggi-do (KR)

(21) Appl. No.: 12/980,983

(22) Filed: Dec. 29, 2010

(30) Foreign Application Priority Data
Feb. 12, 2010 (KR) 10-2010-0013266

(51) Int. Cl. G11C 11/00; H01L 21/8242

(52) U.S. Cl. 365/148; 438/634; 257/E21.646

(57) ABSTRACT

A non-volatile memory device having a three-dimensional (3D) structure includes a plurality of line-type horizontal electrode structures configured to include a plurality of interlayer dielectric layers and a plurality of horizontal electrodes that are alternately stacked over a substrate, a plurality of pillar-type vertical electrodes configured to protrude from the substrate while contacting sidewalls of the plurality of the horizontal electrode structures, and a memory layer interposed between the plurality of the horizontal electrode structures and the plurality of the vertical electrodes, and configured to have a resistance value that varies based on a bias applied to the plurality of the horizontal electrodes and the plurality of the vertical electrodes.

### CROSS-REFERENCE TO RELATED APPLICATIONS

The present application claims priority of Korean Patent Application No. 10-2010-0013265, filed on Feb. 12, 2010, which is incorporated herein by reference in its entirety.

### BACKGROUND OF THE INVENTION

Exemplary embodiments of the present invention relate to a semiconductor device and a method for fabricating the same, and more particularly, to a non-volatile memory device having a three-dimensional (3D) structure, and a method for fabricating the same.

A non-volatile memory device retains a data stored therein although it is cut off from a power source. As a two-dimensional (2D) memory device, which is formed in a layer over a silicon substrate, reaches the limits of improvement in the integration degree thereof, a non-volatile memory device having a 3D structure in which memory cells are stacked vertically over a silicon substrate is introduced.

Hereafter, a structure of a conventional non-volatile memory device having a 3D structure and its disadvantages are described with reference to FIG. 1.

FIG. 1 is a cross-sectional view illustrating a structure of a conventional non-volatile memory device having vertical channels and a method for fabricating the same.

Referring to FIG. 1, a plurality of interlayer dielectric layers 11 and a conductive layer 12 are alternately formed over a substrate 10 with a source region (not shown) formed therein, and a trench exposing the surface of the substrate 10 is formed by etching the plurality of the interlayer dielectric layers 11 and the conductive layer 12. Subsequently, a gate insulation layer 13 is formed on the internal walls of the trench and then a channel CH is formed by filling the trench with a channel-forming layer. As a result, a lower select transistor LST is formed.

A plurality of interlayer dielectric layers 14 and a plurality of conductive layers 15 are alternately formed over the substrate structure with the lower select transistor LST. Herein, the number of interlayer dielectric layers 14 and the number of conductive layers 15 are determined based on the number of memory cells to be stacked.

Subsequently, a trench exposing the channel CH of the lower select transistor LST is formed by etching the plurality of the interlayer dielectric layers 14 and the plurality of the conductive layers 15. After a charge blocking layer, a charge trapping layer, and a tunnel insulation layer (collectively designated with reference numeral 16) are sequentially formed on the internal walls of the trench, the trench is filled with a channel-forming layer so as to form a channel CH. As a result, a plurality of memory cells MC is formed.

Subsequently, a plurality of interlayer dielectric layers 17 and a conductive layer 18 are formed over the plurality of the memory cells MC, and then a trench exposing the channel CH of the plurality of the memory cells MC is formed by etching the plurality of the interlayer dielectric layers 17 and the conductive layer 18.

Subsequently, a gate insulation layer 19 is formed on the internal walls of the trench and then the trench is filled with a channel-forming layer so as to form a channel CH. As a result, an upper select transistor UST is formed.

Herein, the plurality of the memory cells MC are serially coupled between the lower select transistor LST and the upper select transistor UST to form a string. As described above, the integration degree of a non-volatile memory device may be improved by arranging the string vertically from the substrate 10, compared with a plane-type non-volatile memory device.

However, according to the conventional technology described above, a channel is to be formed for the on/off operation of a MOS transistor of a non-volatile memory device. Also, a space for storing a data by trapping charges such as the tunnel insulation layer, the charge trapping layer, and the charge blocking layer is to be provided. Therefore, the size of a memory cell increases to secure such space, and accordingly, the production cost of the memory device may increase.

### SUMMARY OF THE INVENTION

Exemplary embodiments of the present invention are directed to a non-volatile memory device having a three-dimensional structure that may operate without a channel, and a method for fabricating the same.

In accordance with an exemplary embodiment of the present invention, a non-volatile memory device having a three-dimensional (3D) structure includes a plurality of line-type horizontal electrode structures configured to include a plurality of interlayer dielectric layers and a plurality of horizontal electrodes that are alternately stacked over a substrate, a plurality of pillar-type vertical electrodes configured to protrude from the substrate while contacting sidewalls of the plurality of the horizontal electrode structures, and a memory layer interposed between the plurality of the horizontal electrode structures and the plurality of the vertical electrodes, wherein a resistance value of the memory layer is varied based on a bias applied to the plurality of the horizontal electrodes and the plurality of the vertical electrodes.

In accordance with another exemplary embodiment of the present invention, a method for fabricating a non-volatile memory device having a three-dimensional (3D) structure includes forming a plurality of line-type horizontal electrode structures over a substrate, forming a plurality of memory layers contacting sidewalls of the plurality of the horizontal electrode structures, and forming a plurality of pillar-type vertical electrodes protruding from the substrate while contacting the memory layers.

### BRIEF DESCRIPTION OF THE DRAWINGS

FIG. 1 is a cross-sectional view illustrating a structure of a conventional non-volatile memory device having vertical channels and a method for fabricating the same.

FIGS. 2A to 14B are plan views and cross-sectional views describing a method for fabricating a non-volatile memory device having a three-dimensional (3D) structure in accordance with an exemplary embodiment of the present invention.

FIG. 14C illustrates a memory cell in accordance with an exemplary embodiment of the present invention.

FIGS. 15A and 15B are cross-sectional views illustrating a non-volatile memory device having a 3D structure in accordance with an exemplary embodiment of the present invention.

FIG. 16 is a layout of the non-volatile memory device having a 3D structure in accordance with an exemplary embodiment of the present invention.

FIG. 17A is a cross-sectional view of a non-volatile memory device having an odd bit line and an even bit line in accordance with an exemplary embodiment of the present invention.

FIG. 17B is an equivalent circuit diagram of the odd bit line and the even bit line.

FIGS. 18A and 18B are circuit diagrams illustrating a read operation of a non-volatile memory device having a 3D structure in accordance with an exemplary embodiment of the present invention.

FIG. 19 is a circuit diagram illustrating a program operation of a non-volatile memory device having a 3D structure in accordance with an exemplary embodiment of the present invention.

FIG. 20 is a circuit diagram illustrating an erase operation of a non-volatile memory device having a 3D structure in accordance with an exemplary embodiment of the present invention.

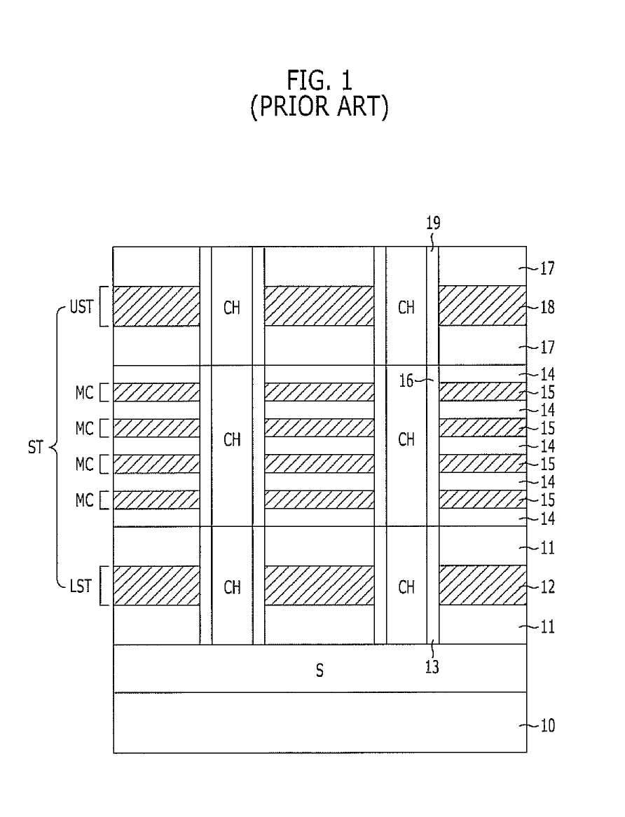

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate, but also a case where a third layer exists between the first layer and the second layer or the substrate.

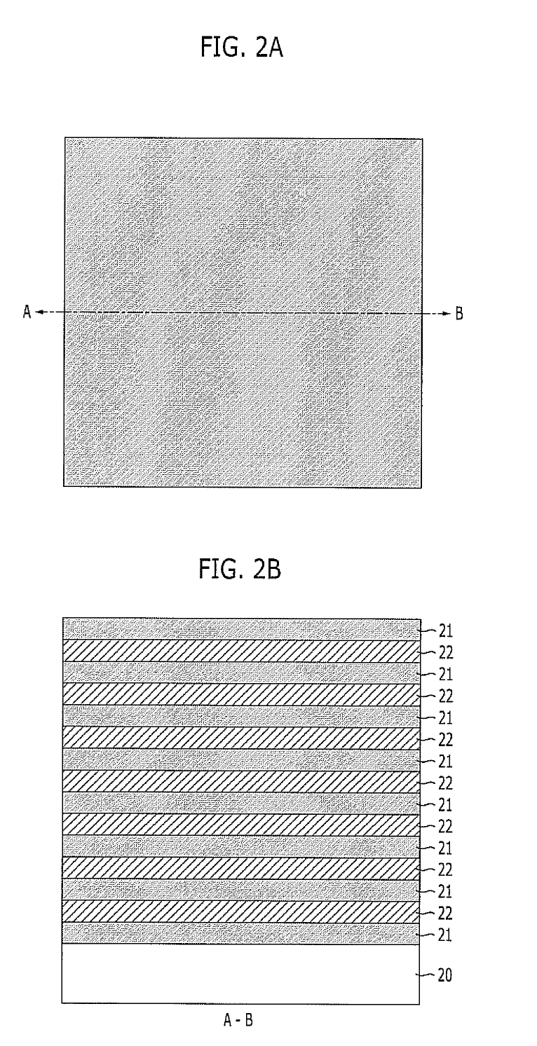

FIGS. 2A to 14B are plan views and cross-sectional views describing a method for fabricating a non-volatile memory device having a three-dimensional (3D) structure in accordance with an exemplary embodiment of the present invention.

With regards to FIGS. 2A to 14B, figures with the same number show corresponding plan views and cross-sectional views of the same stage during the method of fabrication. The cross-sectional views show a cross-section of the non-volatile memory device along a line drawn in the corresponding plan view. Also, in the drawings, the different views may be shown with different magnifications.

Referring to FIGS. 2A and 2B, a plurality of first interlayer dielectric layers 21 and a plurality of first conductive layers 22 are alternately formed over a substrate 20. Herein, the number of the first interlayer dielectric layers 21 and the number of the first conductive layers 22 are determined based on the number of memory cells to be stacked.

Herein, since the plurality of the first conductive layers 22 are formed for forming horizontal electrodes for the operation of memory cells in a subsequent process, they may be polysilicon layers. Also, since the plurality of the first interlayer dielectric layers 21 are formed for isolating the plurality of the horizontal electrodes from each other, they may be oxide layers.

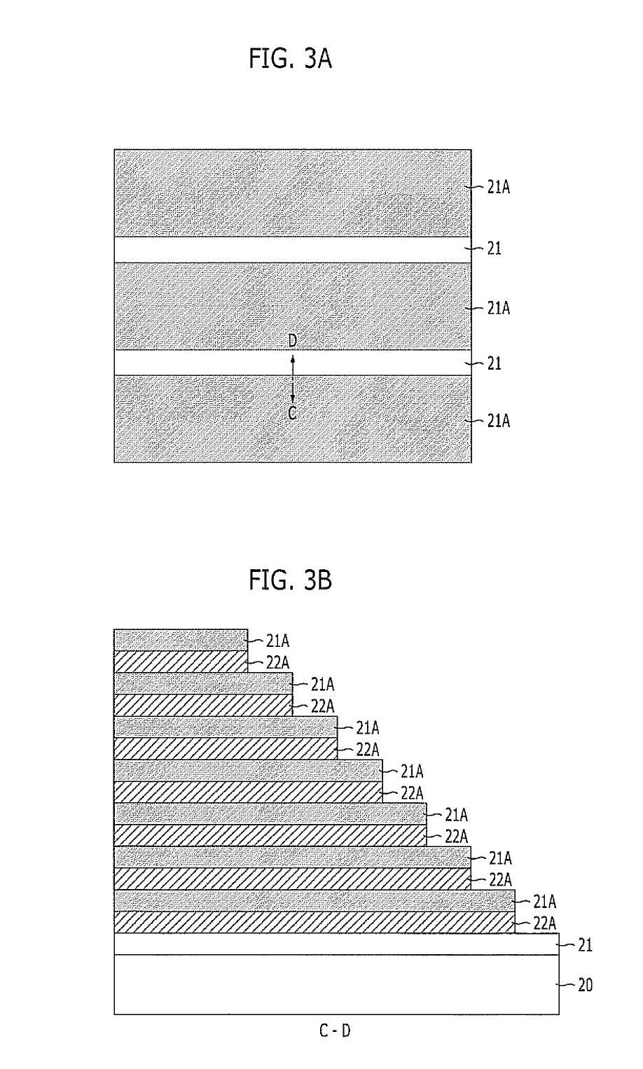

Referring to FIGS. 3A and 3B, the plurality of the first interlayer dielectric layers 21 and the plurality of the first conductive layers 22, which are formed over the substrate 20, are etched to form a plurality of memory blocks isolated from each other.

The horizontal electrodes, formed in a subsequent process, transfer signals applied thereto to corresponding memory cells to perform a program/erase operation. If a horizontal electrode is too long, driving current may be decreased and a signal transfer rate may be deteriorated. Therefore, the lengths of the horizontal electrodes may be controlled by isolating the memory blocks from each other.

Subsequently, the sidewalls of the memory blocks may be patterned into the shape of stairs by etching the plurality of the first interlayer dielectric layers 21 and the plurality of the first conductive layers 22. Herein, respective layers, including one first interlayer dielectric layer 21 and one first conductive layer 22, are patterned as one unit. Through the patterning process, each of the first interlayer dielectric layers 21 may be exposed. Also, as shown in the drawings, it is not necessary to etch the lowermost first interlayer dielectric layer 21. In order to illustrate the contrast between the lowermost first interlayer dielectric layer 21 and the remaining first interlayer dielectric layers 21, the lowermost first interlay dielectric layer 21 is unshaded in the figures described below even though it may be formed of the same material as the other first interlayer dielectric layers 21.

In FIGS. 3A and 3B, the first interlayer dielectric layers 21 and the first conductive layers 22 are referred to as first interlayer dielectric layer patterns 21A and first conductive layer patterns 22A, respectively, after being patterned into the shape of stairs.

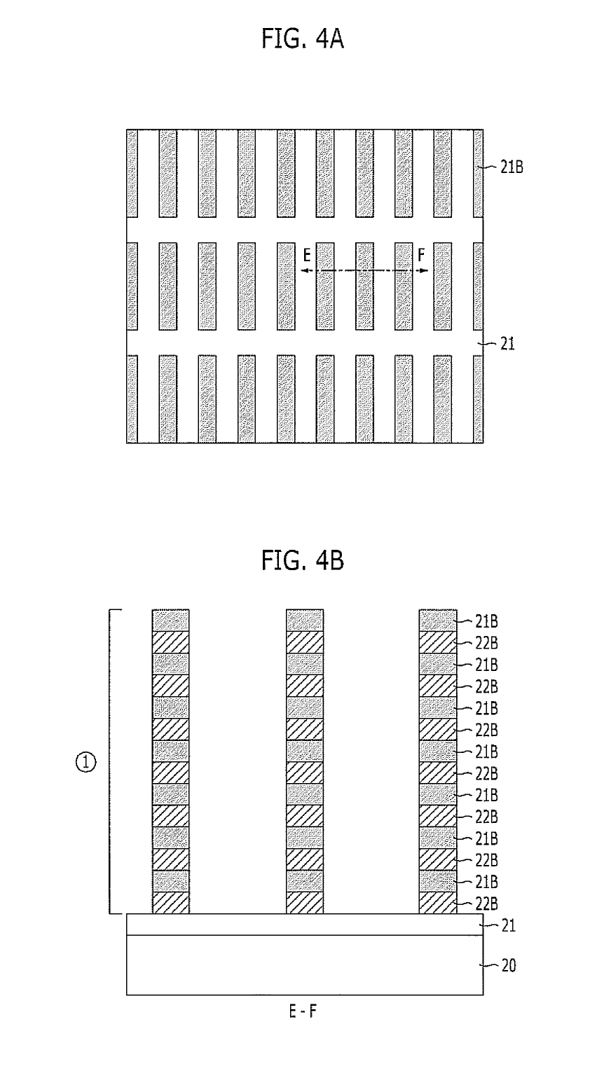

Referring to FIGS. 4A and 4B, the plurality of the first interlayer dielectric layer patterns 21A and the plurality of the first conductive layer patterns 22A are etched to form line-type horizontal electrode structures 1. Each of the line-type horizontal electrode structures 1 include a plurality of interlayer dielectric layers 21B and a plurality of horizontal electrodes 22B that are stacked alternately.

Herein, the memory blocks are divided into the plurality of the horizontal electrode structures 1. In the etched region, which is a gap region between adjacent horizontal electrode structures 1, a vertical electrode for the operation of a memory cell is formed through a subsequent process.

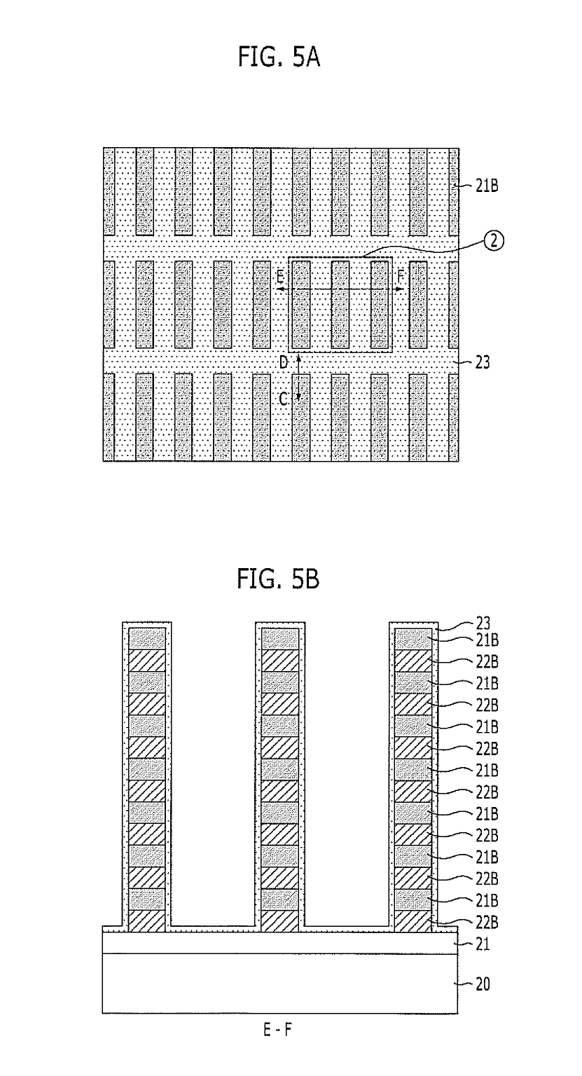

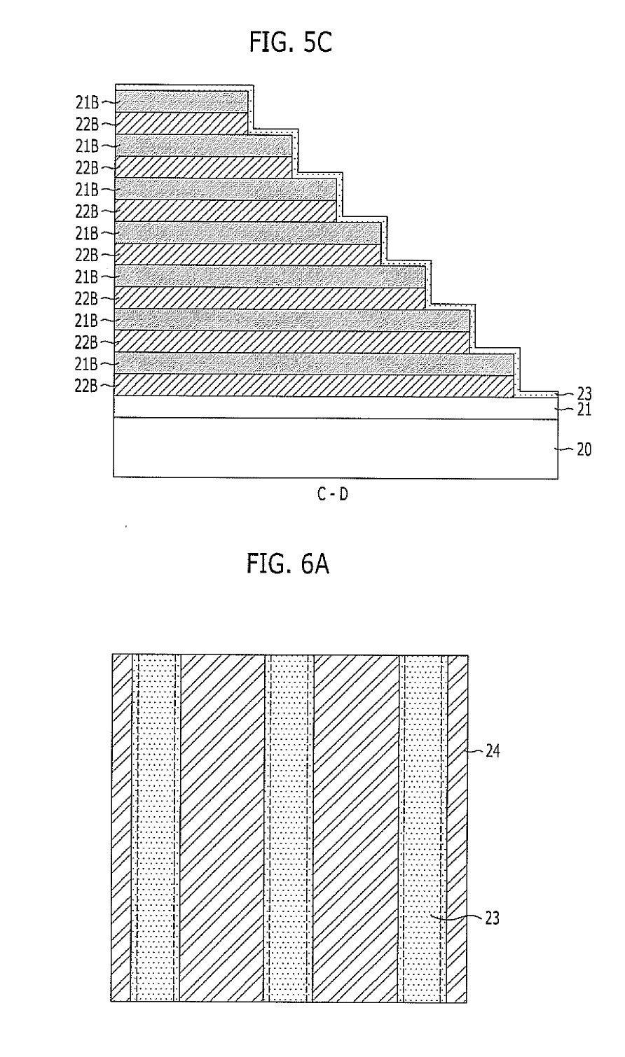

Referring to FIGS. 5A to 5C, an etch stop layer 23 is formed over the profile of the plurality of the horizontal electrode structures 1.

Herein, the etch stop layer 23 protects the plurality of the horizontal electrodes 22B included in the plurality of the horizontal electrode structures 1 from being damaged during a subsequent process and is used as a stop layer during a planarization process. The etch stop layer 23 may be a nitride layer.

Hereafter, for the sake of convenience in description, a magnified plan view of some area 2 of FIG. 5A is referred to.

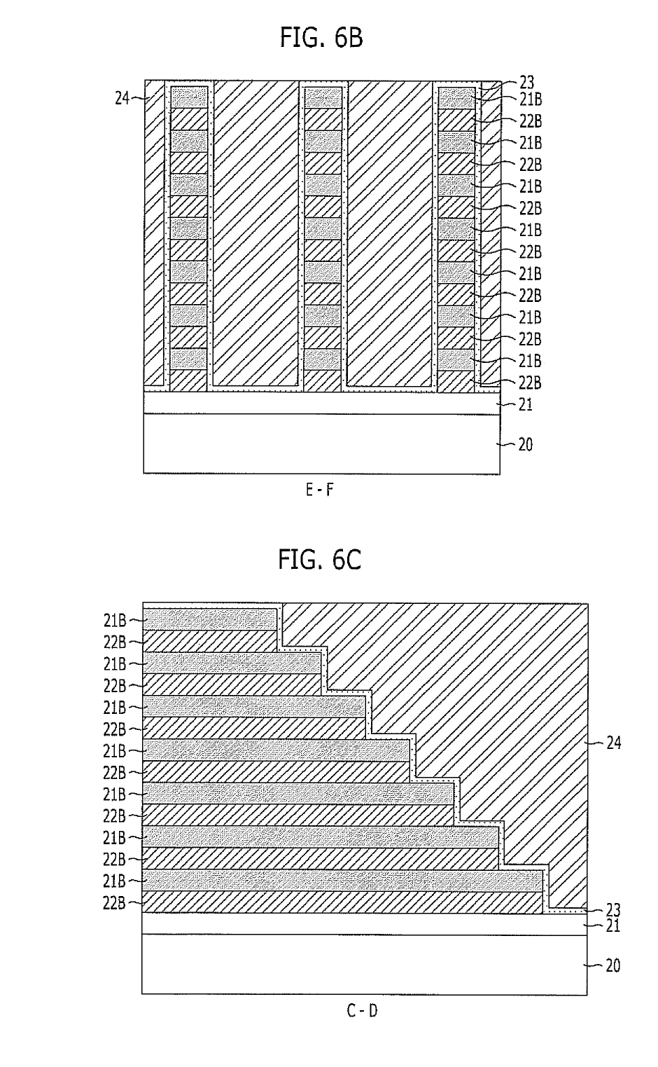

Referring to FIGS. 6A to 6C, a first sacrificial layer 24 is formed over the substrate structure with the etch stop layer 23, and then a planarization process is performed until the surface of the etch stop layer 23 on the uppermost interlayer dielectric layers 21B is exposed. As a result of the planarization process, the gap region between adjacent horizontal electrode structures 1 is filled with the first sacrificial layer 24.

Herein, the dotted line of FIG. 6A indicates an area where the plurality of the interlayer dielectric layers 21B and the plurality of the horizontal electrodes 22B are alternately stacked in the horizontal electrode structures 1.

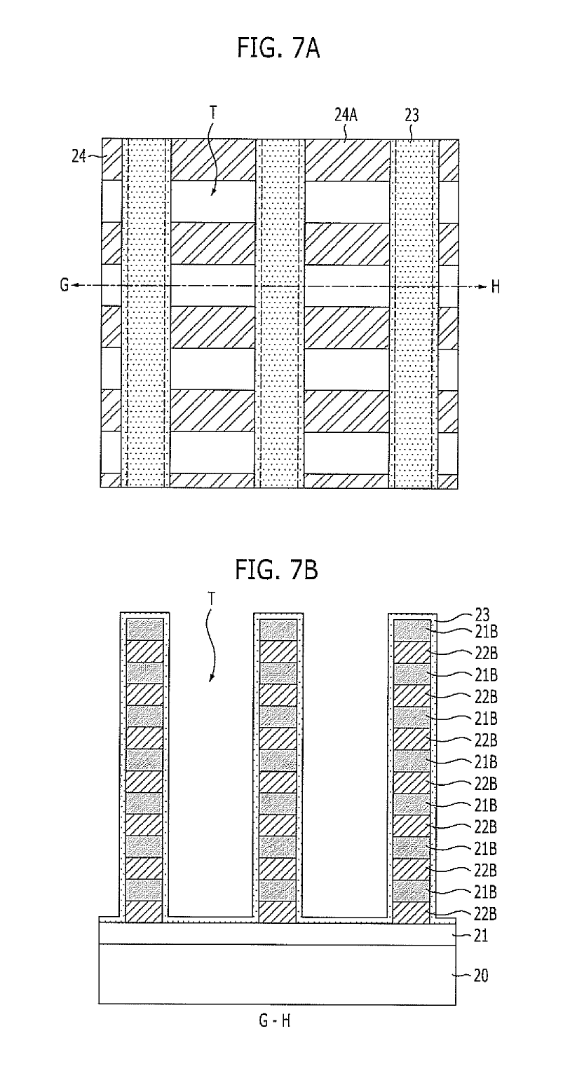

Referring to FIGS. 7A and 7B, first trenches T are formed by etching the first sacrificial layer 24 in lines across the horizontal electrode structures 1. Through the internal walls of the first trenches T, the sidewalls of the horizontal electrode structures 1 with the etch stop layer 23 formed thereon are exposed.

In the drawing, the first sacrificial layer 24 remaining after the etch process for forming the first trenches T is referred to as a first sacrificial layer pattern 24A.

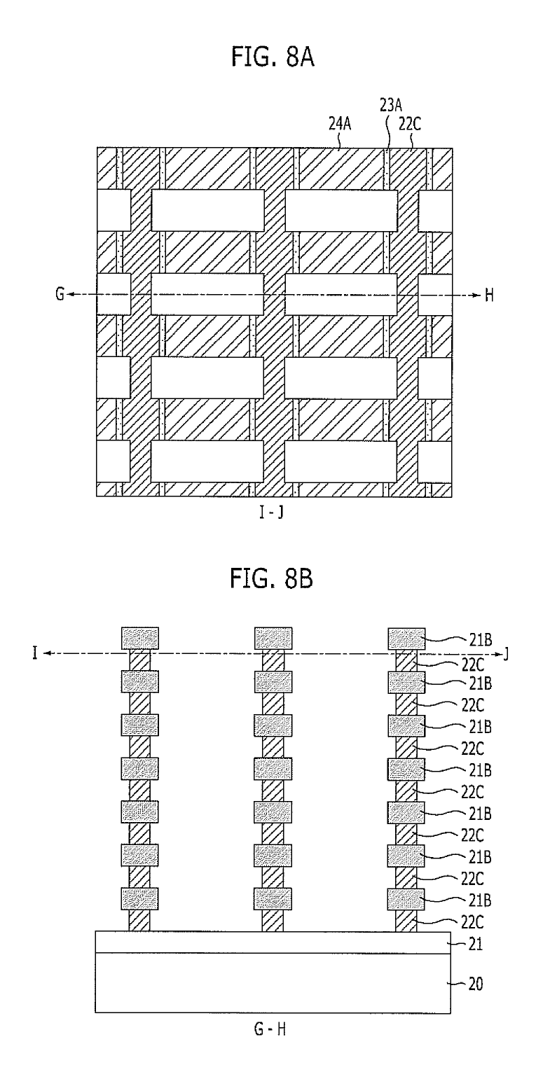

Referring to FIGS. 8A and 8B, the etch stop layer 23, exposed through the internal walls of the first trenches T, is removed. Herein, the etch stop layer interposed between the first sacrificial layer pattern 24A and the horizontal electrode structures 1remains, and the remaining etch stop layer is referred to as an etch stop layer pattern 23A.

Subsequently, the plurality of the horizontal electrodes 22B exposed due to the removal of the etch stop layer 23 are etched to a predetermined thickness. Through the etch process, a region for burying a metal layer for forming a Schorttky diode in a subsequent process is prepared. In the drawings, the horizontal electrodes which are etched to the predetermined thickness are referred to as etched horizontal electrodes 22C.

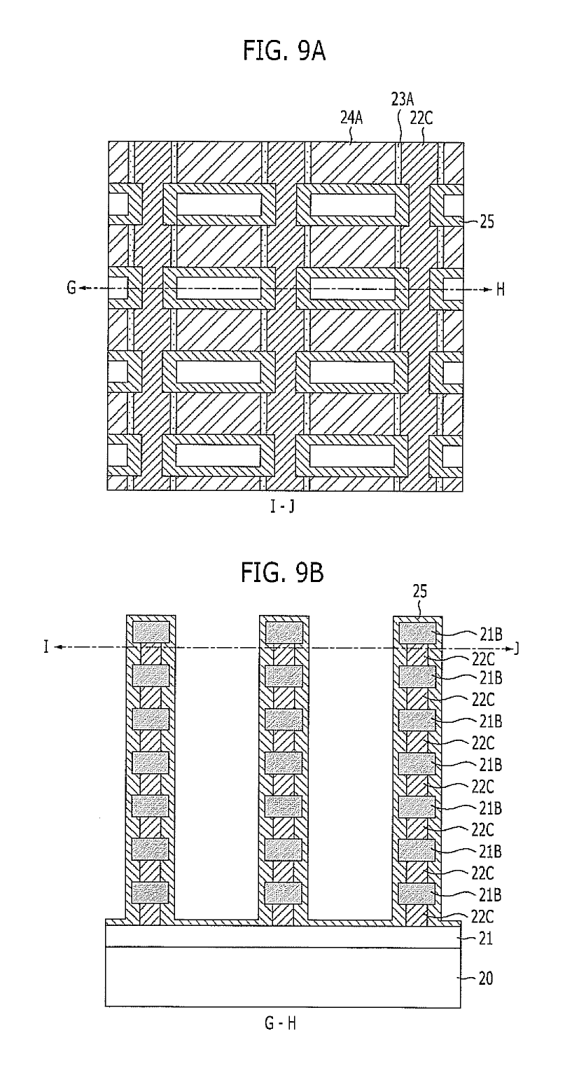

Referring to FIGS. 9A and 9B, a metal layer 25 is formed over the profile of the horizontal electrode structures 1 of the etched horizontal electrodes 22C. Herein, the metal layer 25 may be formed to a thickness to completely fill the etched regions of the etched horizontal electrodes 22C.

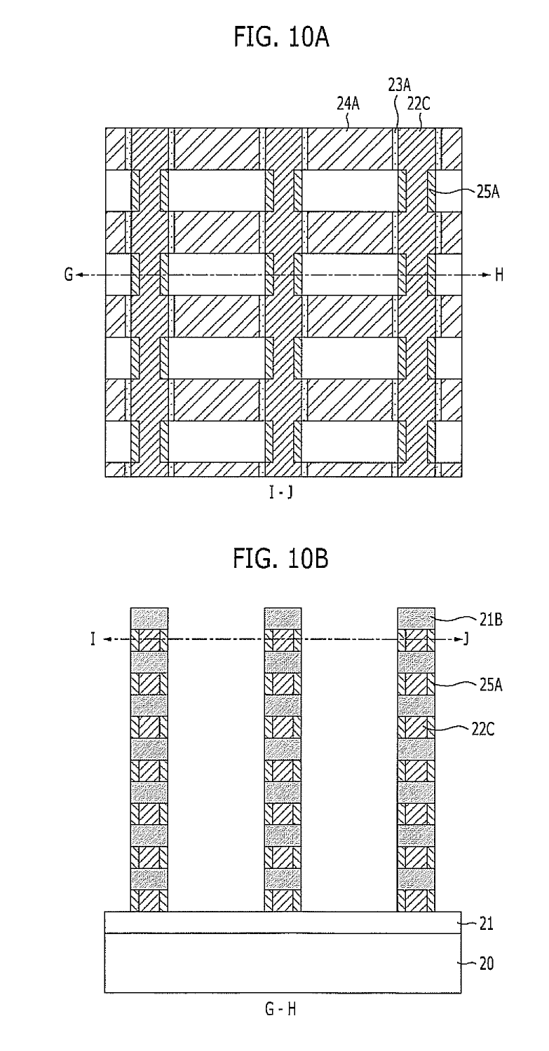

Referring to FIGS. 10A and 10B, an anisotropic etch process is performed to remove the metal layer 25 formed on the sidewalls of the horizontal electrode structures 1 and the bottom of the first trenches T while the metal layer 25 filling the etched regions remains. The remaining metal layer 25, existing in the etched regions after the anisotropic etch process, is referred to as a metal layer pattern 25A. As a result of the anisotropic etch process, a Schorttky diode formed of the etched horizontal electrodes 22C and the metal layer pattern 25A is formed. The Schorttky diode is used as a sort of selection device.

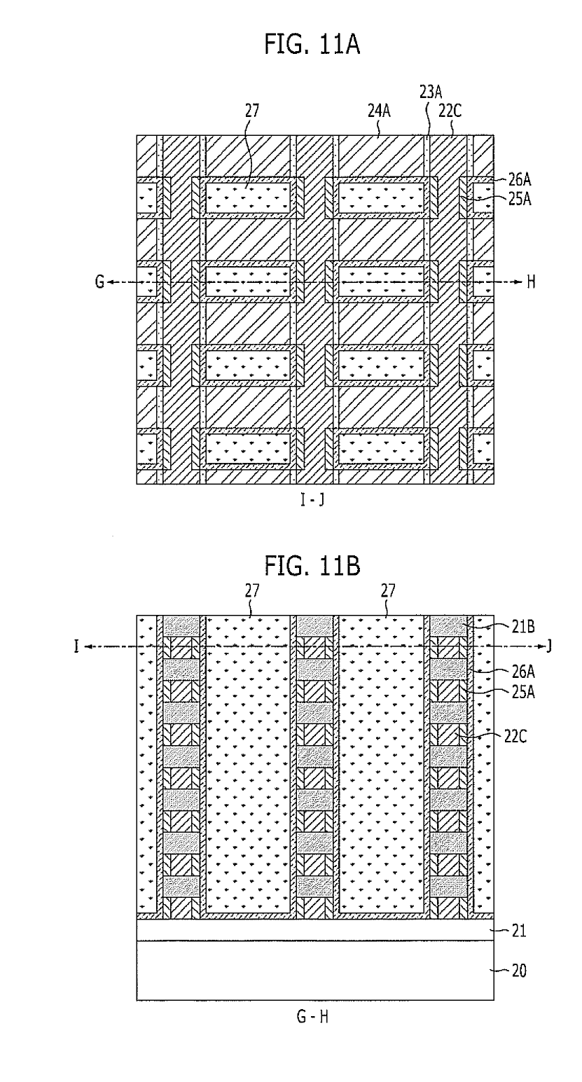

Referring to FIGS. 11A and 11B, a memory-forming material layer is formed on the internal walls and bottom of the first trenches T after the metal layer pattern 25A is filled in the etched regions.

Herein, the memory-forming material layer is a layer for storing data. The memory-forming material layer has a resistance value varying based on an external voltage and accordingly current flowing through the layer varies. Therefore, the memory-forming material layer may be formed of a material whose resistance value varies according to a bias applied to the etched horizontal electrodes 22C and a vertical electrode to be formed in a subsequent process. For example, the memory-forming material layer may be formed of a chalcogenide material formed of GeSbTe (Germanium-Antimony-Tellurium) or a tellurium (Te) compound, or PCMO or strontium titanate (SrTiO₃) doped with niobium (Nb).

Subsequently, a vertical electrode-forming conductive layer 27 is formed to fill the first trenches T with the memory-forming material layer formed therein. Herein, the vertical electrode-forming conductive layer 27 may be a polysilicon layer.

Subsequently, a planarization process is performed until the surface of the interlayer dielectric layers 21B is exposed. As a result of the planarization process, the memory-forming material layer contacting the sidewalls of the horizontal electrode structures 1 are formed and referred to as a plurality of memory layers 26A.

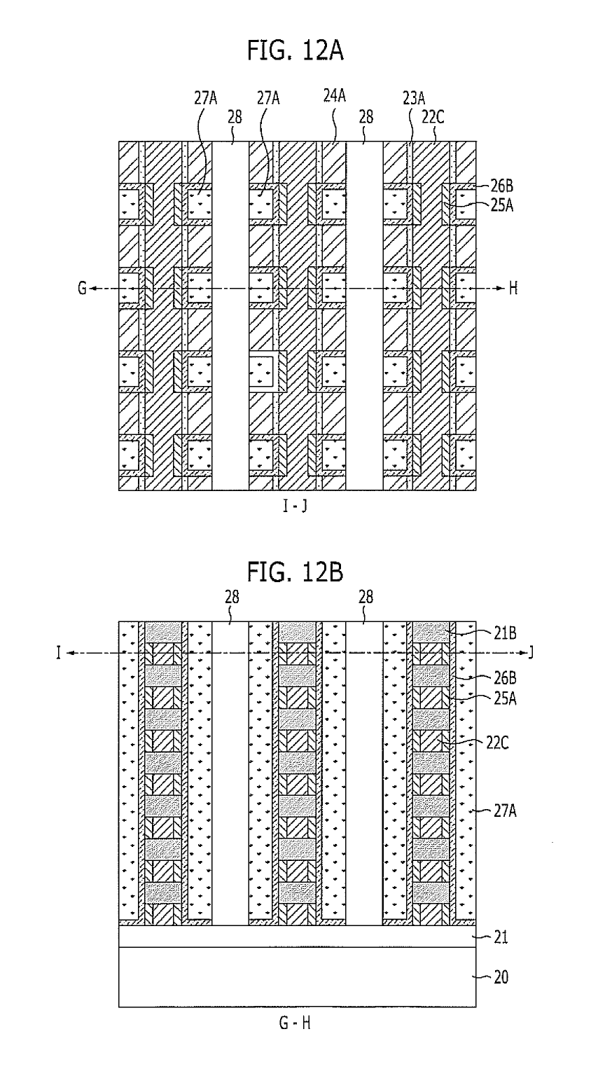

Referring to FIGS. 12A and 12B, a plurality of vertical electrodes 27A contacting the sidewalls of adjacent horizontal electrode structures 1 are formed by etching the central portion of the vertical electrode-forming conductive layer 27 buried in the inside of the first trenches T. Herein, while the vertical electrode-forming conductive layer 27 is etched, a portion of the memory layers 26A formed at the bottom of the first trenches T is also etched. Through this etch process, a plurality of memory layers 26B, contacting the sidewalls of the horizontal electrode structures 1, are isolated from each other.

Subsequently, a second sacrificial 28 fills the central area from which the vertical electrode-forming conductive layer 27 is etched. As a result, a plurality of memory cells stacked along both sidewalls of each horizontal electrode structure 1 are formed. Herein, the plurality of the memory cells stacked along both sidewalls of each horizontal electrode structure 1 are coupled by the vertical electrodes 27A, and a target memory cell may be selected by a selection device, which is a Schottky diode.

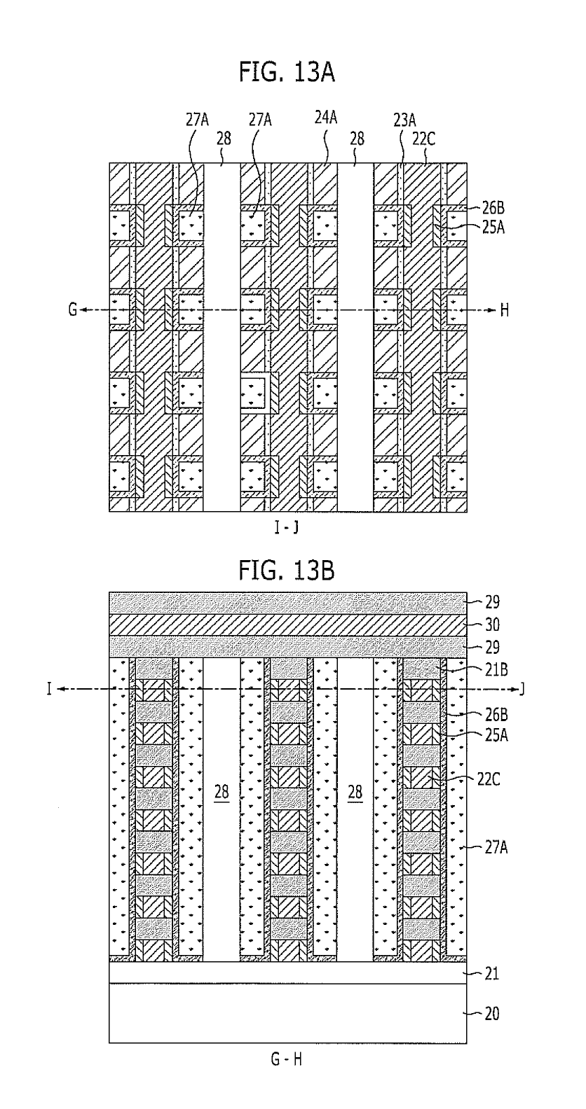

Referring to FIGS. 13A and 13B, a plurality of second interlayer dielectric layers 29 and a second conductive layer 30 are formed to form select transistors over the substrate structure with the plurality of the vertical electrodes 27A.

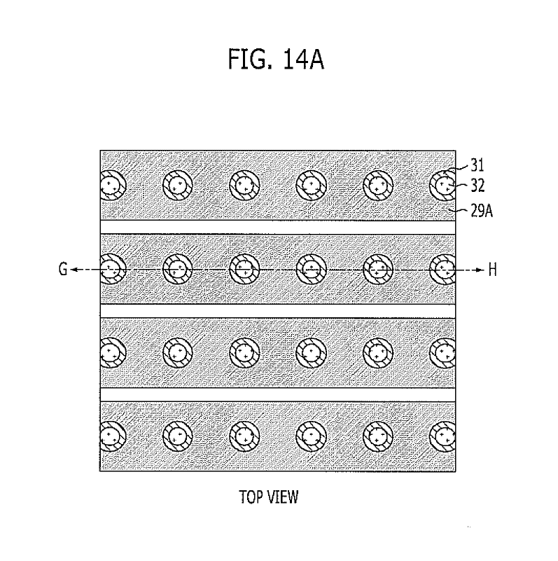

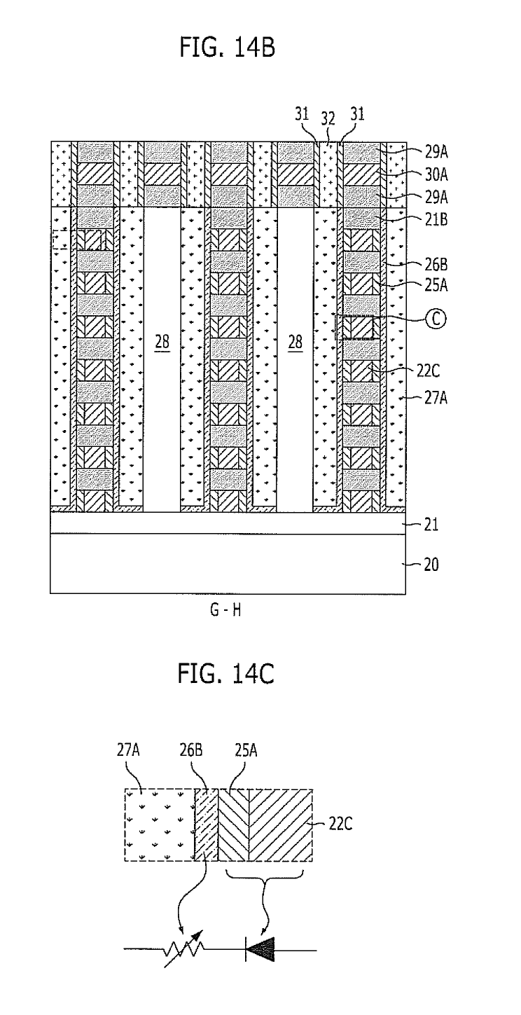

Referring to FIGS. 14A and 14B, a plurality of second trenches exposing the surfaces of the plurality of the vertical electrodes 27A are formed by etching the plurality of the second interlayer dielectric layers 29 and the second conductive layer 30.

Subsequently, a gate insulation layer 31 is formed on the internal walls of the second trenches, and channels 32 are formed by filling the second trenches, having the gate insulation layer 31 formed therein, with a channel-forming layer. As a result, a plurality of select transistors coupled with the plurality of the vertical electrodes 27A are formed.

Subsequently, the plurality of the second interlayer dielectric layers 29 and the second conductive layer 30 are etched in lines across the horizontal electrode structures 1. As a result of the etch process, the vertical electrodes 27A arranged in a direction crossing the horizontal electrode structures 1 are coupled to the same select line.

FIG. 14C illustrates a memory cell in accordance with an exemplary embodiment of the present invention, which magnifies and shows some area C of FIG. 14B.

As illustrated in FIG. 14C, a memory cell includes a vertical electrode 27A, a memory layer 26B, a metal layer pattern 25A, and an etched horizontal electrode 22C. Herein, the metal layer pattern 25A and the etched horizontal electrode 22C constitute a Schottky diode and it functions as a sort of selection device. Also, the memory layer 26B may have a resistance value varying based on a bias applied to the vertical electrode 27A and the etched horizontal electrode 22C and may store data in the memory cell.

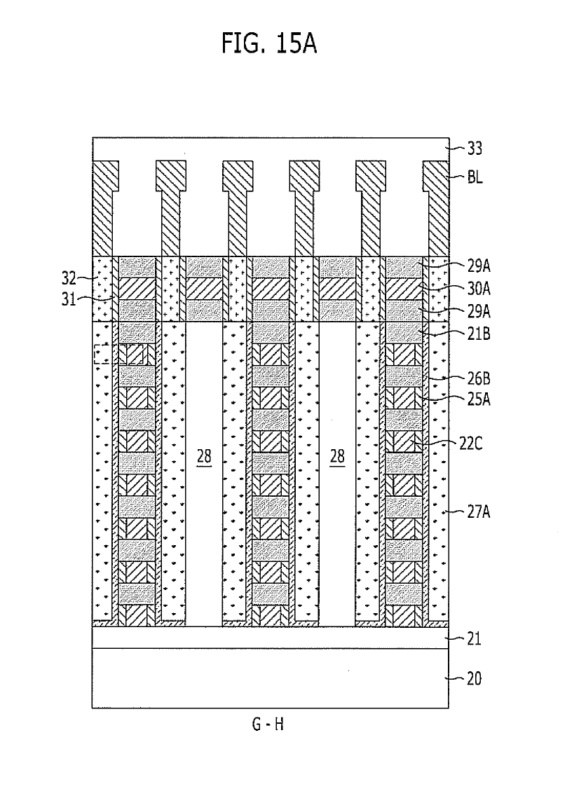

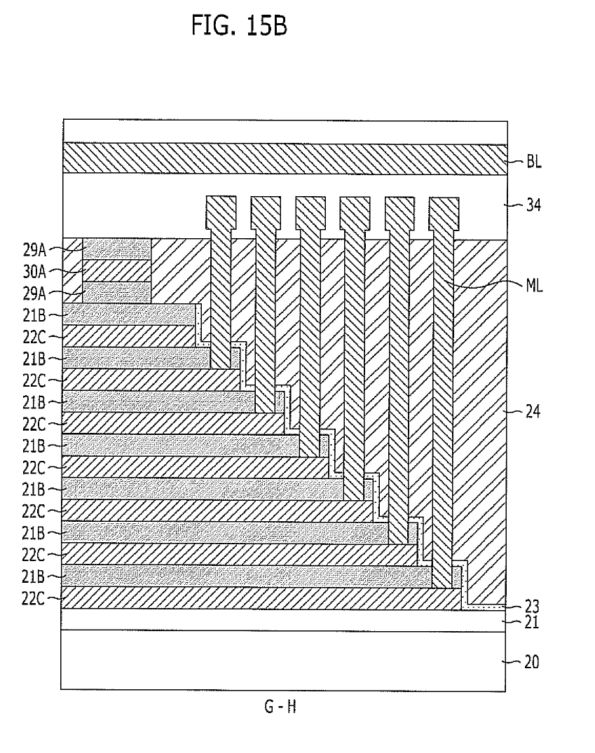

FIGS. 15A and 15B are cross-sectional views illustrating a non-volatile memory device having a 3D structure in accordance with an exemplary embodiment of the present invention.

Referring to FIG. 15A, a plurality of bit lines BL are formed over the plurality of the select transistors. Herein, the bit lines BL may be formed to be coupled with the plurality of the select transistors. In FIG. 15A, reference numeral ‘33’ denotes an interlayer dielectric layer.

Referring to FIG. 15B, a plurality of metal lines ML respectively coupled with the plurality of the etched horizontal electrodes 22C included in the horizontal electrode structures 1 are formed. In FIG. 15B, reference numeral ‘34’ denotes an interlayer dielectric layer.

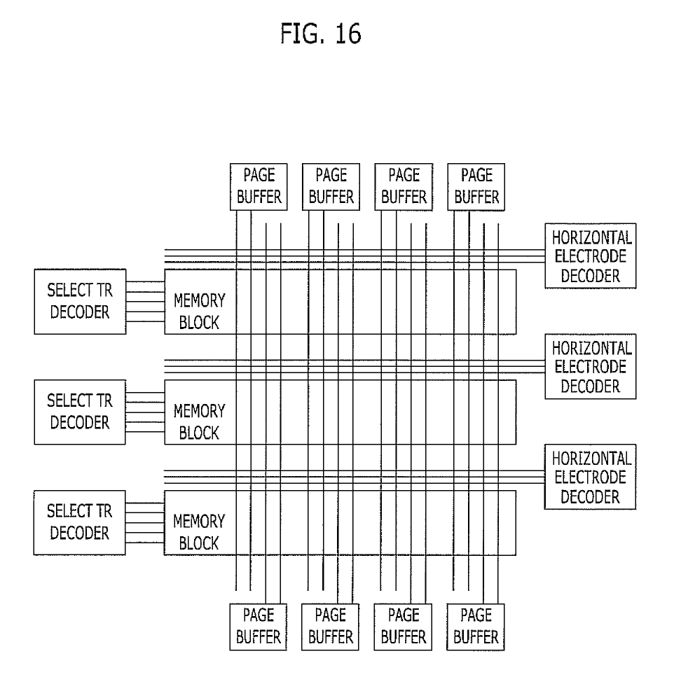

FIG. 16 is a layout of the non-volatile memory device having a 3D structure in accordance with an exemplary embodiment of the present invention. In the FIG. 16, the horizontal electrode structures are not separately illustrated. Instead, only memory block regions are shown for the sake of convenience in description.

Each memory block includes the plurality of the horizontal electrode structures 1, and a plurality of memory cells are stacked using the memory blocks.

A page buffer transfers signals to the plurality of the memory cells through bit lines BL, and with the page buffer, a memory cell is programmed/erased, or data stored in a memory cell is read. Herein, one page buffer is coupled with at least two bit lines BL.

A horizontal electrode decoder transfers a signal through the metal lines ML respectively coupled with the etched horizontal electrodes 22C included in the horizontal electrode structures 1 and selects the etched horizontal electrode 22C coupled with a memory cell to perform a predetermined operation.

A select transistor decoder is coupled with a select line formed in the upper portion of the horizontal electrode structures 1. Therefore, it selects a select transistor coupled with a vertical electrode 27A of the memory cell which performs a predetermined operation and transfers a signal.

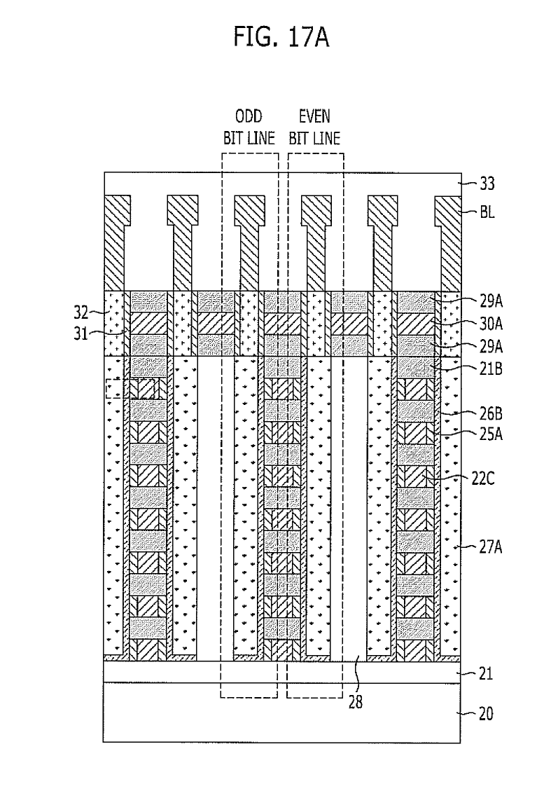

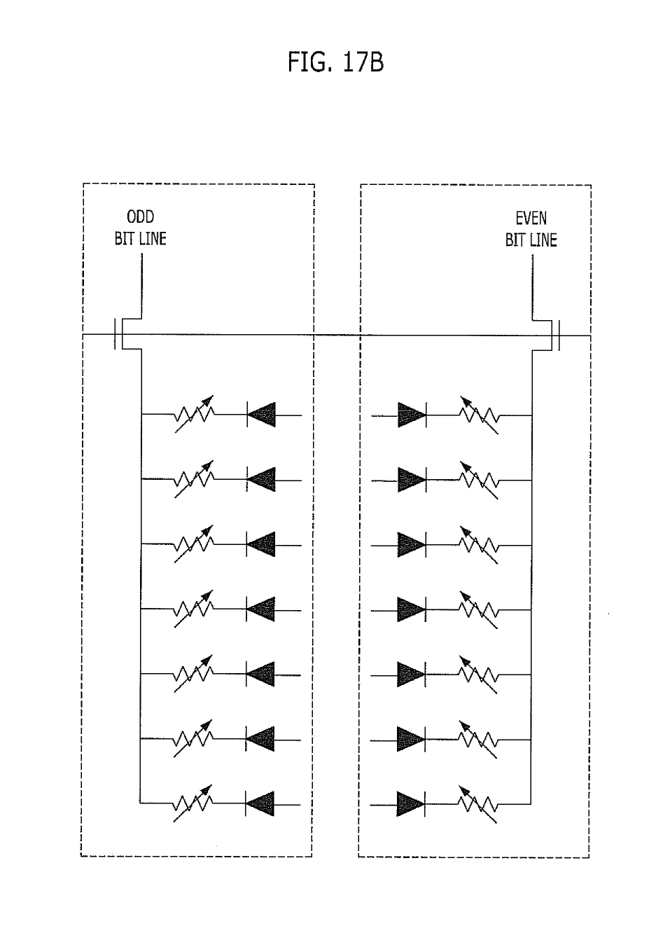

FIG. 17A is a cross-sectional view of a non-volatile memory device having an odd bit lien and an even bit line in accordance with an exemplary embodiment of the present invention. FIG. 17B is an equivalent circuit diagram of the odd bit line and the even bit line.

As illustrated in the drawings, a plurality of memory cells are stacked along both sidewalls of each horizontal electrode structure 1. Herein, a bit line coupled with the memory cells stacked along one sidewall of the horizontal electrode structure 1 is defined as an odd bit line, whereas a bit line coupled with the memory cells stacked along the other sidewall of the same horizontal electrode structure 1 is defined as an even bit line.

Herein, the corresponding odd bit lines and even bit lines may be coupled to the same page buffer. The page buffer may select a bit line from among the odd bit line and the even bit line and perform a read operation. Herein, a desired vertical electrode 27A among the plurality of the vertical electrodes 27A coupled to the selected bit line may be selected through the select transistor.

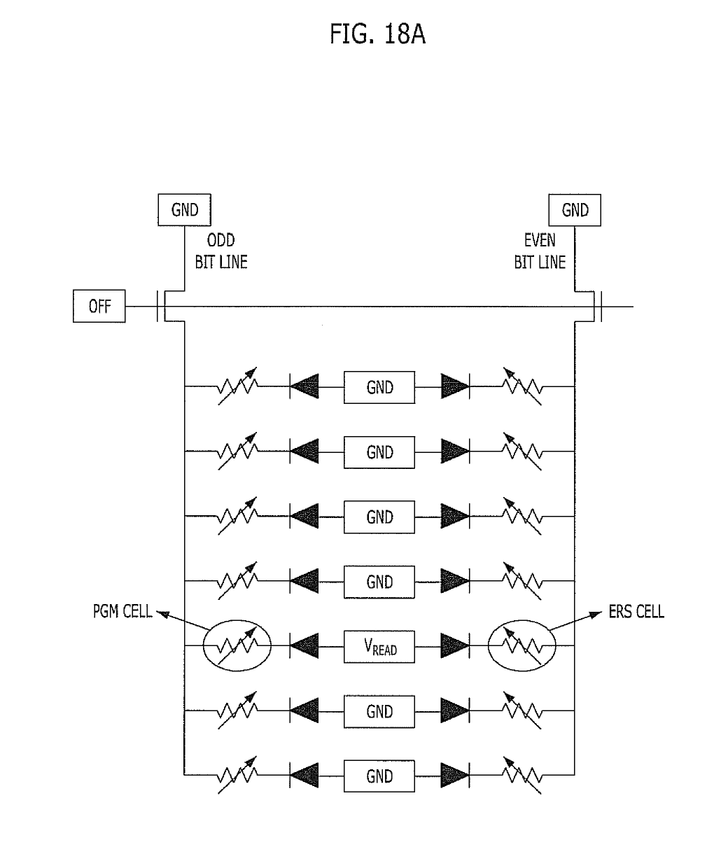

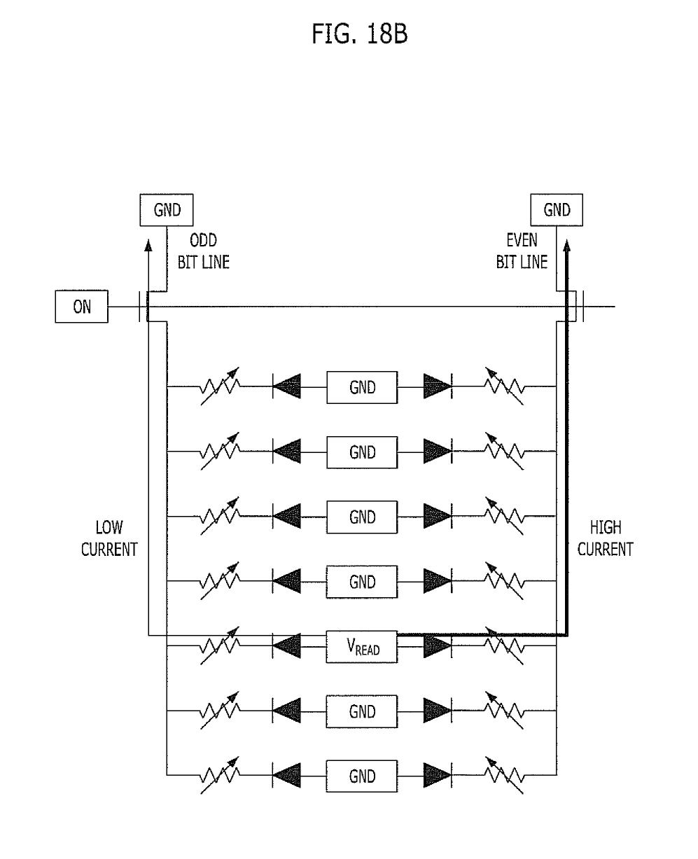

FIGS. 18A and 18B are circuit diagrams illustrating a read operation of a non-volatile memory device having a 3D structure in accordance with an exemplary embodiment of the present invention.

Referring to FIG. 18A, the plurality of the select transistors are turned off and the plurality of the bit lines are electrically isolated from the memory cells. Subsequently, a read voltage V_{READ} is applied to an etched horizontal electrode 22C of a memory cell selected to be read, while the etched horizontal electrodes 22C of the other memory cells (i.e., unselected memory cells) are grounded. Here, the plurality of the bit lines are grounded.

Referring to FIG. 18B, the plurality of the select transistors are turned on to sense the level of current flowing through the bit lines. Here, when the selected memory cell is programmed (see program cell PGM CELL in FIG. 18A), the memory layer 26B has a high resistance. Thus, a low level of current is sensed. On the other hand, when the selected memory cell is erased (see erased cell ERS CELL in FIG. 18A), the memory layer 26B has a low resistance. Thus, a high level of current is sensed.

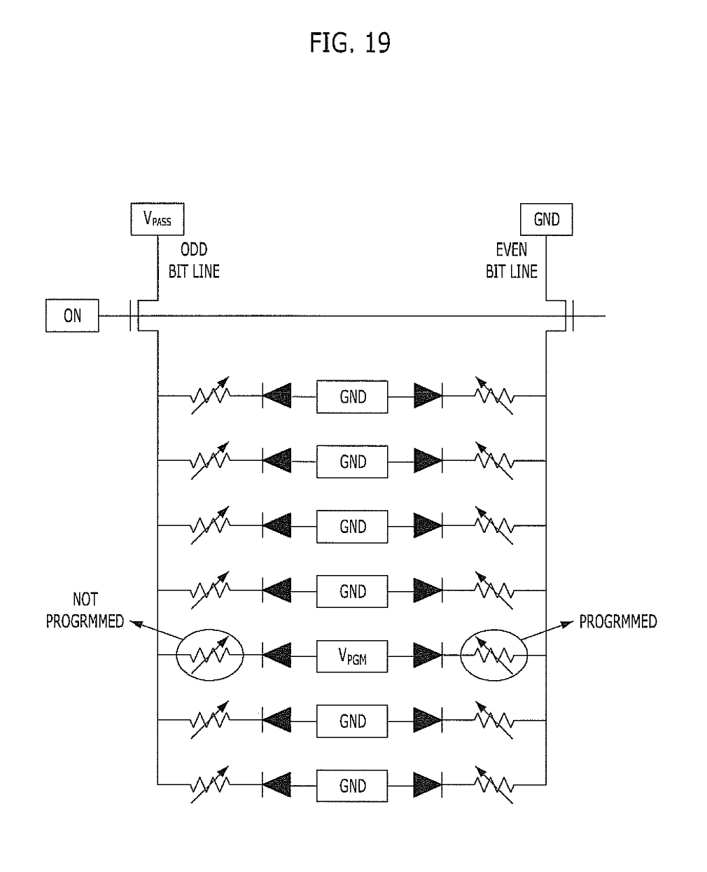

FIG. 19 is a circuit diagram illustrating a program operation of a non-volatile memory device having a 3D structure in accordance with an exemplary embodiment of the present invention.

As illustrated in the FIG. 19, the bit line coupled with the memory cell selected to be programmed is grounded and a pass voltage V_{PASS} is applied to the other bit lines. Subsequently, a program voltage V_{PGM} is applied to an etched horizontal electrode 22C of a selected memory cell, while the etched horizontal electrodes 22C of the other memory cells (i.e., unselected memory cells) are grounded. Subsequently, the plurality of the select transistors are turned on.

According to the above-described operation, the resistance value of the memory layer 26B of the selected memory cell varies based on the bias difference (GNDV_{PGM}) between the vertical electrode 27A and the etched horizontal electrode 22C thereof. On the other hand, in the other memory cells, the etched horizontal electrodes 22C are grounded and the pass voltage V_{PASS} is applied to the vertical electrode 27A. Therefore, the resistance value of the memory layer 26B does not vary. Thus, even though an unselected memory cell shares an etched horizontal electrode 22C with a selected memory cell, the resistance value of the memory layer 26B of the unselected memory cell does not vary when the program voltage V_{PGM} is applied to the shared etched horizontal electrode 22C because the pass voltage V_{PASS} is applied to the vertical electrode 27A thereof. In this case, since the bias difference (V_{PASS}-V_{PGM}) between the etched horizontal electrode 22C and the vertical electrode 27A is small, the resistance value of the memory layer 26B does not vary.

A program operation may be performed by selecting one between an odd bit line and an even bit line, or it may be performed onto all bit lines.

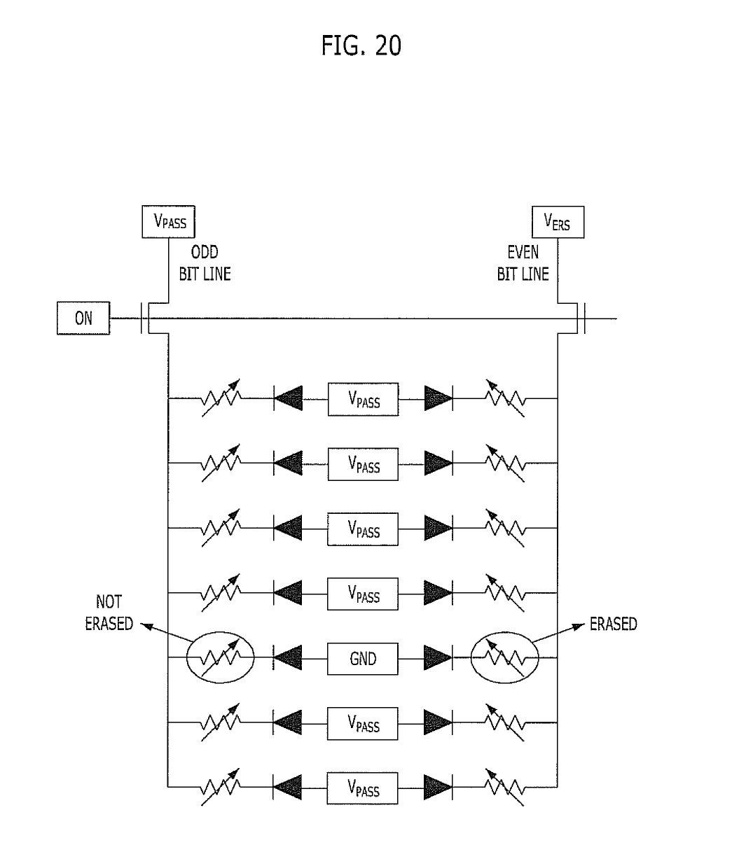

FIG. 20 is a circuit diagram illustrating an erase operation of a non-volatile memory device having a 3D structure in accordance with an exemplary embodiment of the present invention.

As illustrated in FIG. 20, an erase voltage V_{ERS} is applied to the bit line coupled with the memory cell selected to be erased and a pass voltage V_{PASS} is applied to the other bit lines. Subsequently, the etched horizontal electrode 22C of the memory cell selected to be erased is grounded and a pass voltage V_{PASS} is applied to the etched horizontal electrodes 22C of the other memory cells. Subsequently, a select transistor is turned on.

According to the erase operation, the resistance value of the memory layer 26B of the selected memory cell varies due to the bias difference (GND-V_{ERS}) between the etched horizontal electrode 22C and the vertical electrode 27A thereof. On the other hand, a pass voltage V_{PASS} is applied to the etched horizontal electrode 22C and the vertical electrode 27A of the other memory cells, and the resistance value of the memory layer 26B does not vary. Particularly, when a memory cell shares the etched horizontal electrode 22C with the memory cell to be erased and the etched horizontal electrode 22C is grounded, the pass voltage V_{PASS} is applied to the vertical electrode 27A of the memory cell. Therefore, since the bias difference (GND-V_{PASS}) between the etched horizontal electrode 22C and the vertical electrode 27A of the memory cell is small, the resistance value of the memory layer 26B does not vary.

The erase operation may be performed by selecting one between an odd bit line and an even bit line, or it may be performed onto all bit lines.

Exemplary embodiments of the present invention provide a non-volatile memory device having a three-dimensional structure for storing data by using a memory layer whose resistance value varies based on a bias applied to a plurality of horizontal electrodes stacked over a substrate and a plurality of vertical electrodes which protrude from the substrate. Therefore, the non-volatile memory device does not require a channel for on/off operations, a tunnel insulation layer for storing data, a charge trapping layer, and a charge blocking layer. Accordingly, the size of memory cells may decrease and the production cost for the memory device may be reduced.

While the present invention has been described with respect to the specific embodiments, it will be apparent to those skilled in the art that various changes and modifications may be made without departing from the spirit and scope of the invention as defined in the following claims.

What is claimed is:

1. A non-volatile memory device having a three-dimensional (3D) structure, comprising:
a plurality of line-type horizontal electrode structures configured to include a plurality of interlayer dielectric layers and a plurality of horizontal electrodes that are alternately stacked over a substrate;
a plurality of pillar-type vertical electrodes configured to protrude from the substrate while contacting sidewalls of the plurality of the horizontal electrode structures; and
a memory layer interposed between the plurality of the horizontal electrode structures and the plurality of the vertical electrodes,
wherein a resistance value of the memory layer is varied based on a bias applied to the plurality of the horizontal electrodes and the plurality of the vertical electrodes.

2. The non-volatile memory device of claim 1, wherein the plurality of the horizontal electrode structures comprise a metal layer for filling an area formed by etching both sidewalls of each horizontal electrode to a predetermined thickness.

3. The non-volatile memory device of claim 2, wherein one of the horizontal electrodes and the metal layer form a Schottky diode, which is a selection device for selecting a desired memory cell.

4. The non-volatile memory device of claim 1, further comprising:
a plurality of metal lines coupled to the plurality of the horizontal electrodes respectively; and
a horizontal electrode decoder configured to select one of the stacked horizontal electrodes through the plurality of the metal lines.

5. The non-volatile memory device of claim 1, further comprising:
a plurality of select transistors formed over the plurality of the vertical electrodes to be coupled with the plurality of the vertical electrodes respectively; and
a select transistor decoder configured to control the plurality of the select transistors.

6. The non-volatile memory device of claim 5, further comprising:
a plurality of bit lines formed over the plurality of the select transistors to be coupled with the plurality of the select transistors; and
a page buffer coupled with the plurality of the bit lines.

7. The non-volatile memory device of claim 1, wherein the memory device is configured to perform read, program, and erase operations by using a variation of the resistance value of the memory layer according to bias differences between the horizontal electrodes and the plurality of the vertical electrodes.

8. The non-volatile memory device of claim 6, wherein the memory device is configured to perform a read operation of a selected memory cell by turning on the select transistors in a state in which the horizontal electrodes of a selected memory cell are applied with a read voltage, and the other horizontal electrodes of unselected memory cells and the plurality of the bit lines are applied with ground voltage.

9. The non-volatile memory device of claim 6, wherein the memory device is configured to perform a program operation of a selected memory cell by turning on the select transistors in a state in which the bit line and the horizontal electrodes of a selected memory are applied with a ground voltage and a program voltage, respectively, and the other bit lines and the horizontal electrodes of unselected memory cells are applied with a pass voltage and the ground voltage, respectively.

10. The non-volatile memory device of claim 6, wherein the memory device is configured to perform an erase operation of a selected memory cell by turning on the select transistors in a state in which the bit line and the horizontal electrodes of a selected memory are applied with an erase voltage and a ground voltage, respectively, and the other bit lines and the horizontal electrodes of unselected memory cells are applied with a pass voltage.

11. A method for fabricating a non-volatile memory device having a three-dimensional (3D) structure, comprising:
forming a plurality of line-type horizontal electrode structures over a substrate;
forming a plurality of memory layers contacting sidewalls of the plurality of the horizontal electrode structures; and
forming a plurality of pillar-type vertical electrodes protruding from the substrate while contacting the memory layers.

12. The method of claim 11, wherein the forming of the plurality of the line-type horizontal electrode structures comprises:
alternately stacking a plurality of interlayer dielectric layers and a plurality of first conductive layers over the substrate;
etching the plurality of the interlayer dielectric layers and the plurality of the first conductive layers to form a plurality of horizontal electrodes and a trench for exposing the substrate in a line-type;
recessing the etched sidewalls of the plurality of the horizontal electrode to a predetermined thickness; and
filling a recessed area on the sidewalls with a metal layer.

13. The method of claim 12, wherein the recessing of the plurality of the horizontal electrodes comprises:
forming an etch stop layer along a surface of the plurality of the horizontal electrodes after forming the trench;
filling a gap region between the plurality of the horizontal electrode structures with a sacrificial layer;
forming the recessed area exposing the sidewalls of the horizontal electrode structures at predetermined spaces by etching the sacrificial layer in a line across the plurality of the horizontal electrode structures;
removing the etch stop layer exposed through internal sidewalls of the recessed area; and
etching each of the plurality of the horizontal electrodes exposed by the removal of the etch stop layer to the predetermined thickness.

14. The method of claim 13, wherein the forming of the plurality of memory layers contacting the sidewalls of the plurality of the horizontal electrode structures comprises:
forming a memory material layer over a surface of the trenches filled with the metal layer; and
forming a second conductive layer to fill the trenches.

15. The method of claim 14, further comprising:
etching a central region of the second conductive layer to form a plurality of vertical electrodes contacting the sidewalls of adjacent horizontal electrode structures; and
filling the etched central region of the second conductive layer with a sacrificial layer.

16. The method of claim 11, further comprising:
forming a plurality of select transistors coupled with the plurality of the vertical electrodes respectively, after the forming of the plurality of the vertical electrodes.

17. The method of claim 16, wherein the forming of the plurality of the select transistors comprises:
forming a plurality of interlayer dielectric layers and a conductive layer over a substrate structure with the plurality of the vertical electrodes formed;
etching the plurality of the interlayer dielectric layers and the layer to form a plurality of trenches exposing surfaces of the plurality of the vertical electrodes;
forming a gate insulation layer on internal sidewalls of the plurality of the trenches;
forming channels by filling the plurality of the trenches with the gate insulation layer formed; and
etching the plurality of the interlayer dielectric layers and the conductive layer in a line type across the plurality of the horizontal electrode structures.

18. The method of claim 17, further comprising:
forming a plurality of bit lines coupled with the plurality of the select transistors over the plurality of the select transistors.
